(19) United States
(12) Patent Application Publication
(10) Pub. No.: US 2011/0002098 A1
(43) Pub. Date: Jan. 6, 2011

(54) CIRCUIT, SYSTEM AND METHOD FOR CONTROLLING HEAT DISSIPATION FOR MULTIPLE UNITS ON A CIRCUIT BOARD

(75) Inventor: Shuang Xu, Guangdong (CN)

Correspondence Address: NVIDIA C/O MURABITO, HAO & BARNES LLP, TWO NORTH MARKET STREET, THIRD FLOOR, SAN JOSE, CA, 95113, US

(73) Assignee: NVIDIA CORPORATION, Santa Clara, CA (US)

(21) Appl. No.: 12/577,664

(22) Filed: Oct. 12, 2009

(30) Foreign Application Priority Data
Jul. 1, 2009 (CN) 200910148722.0

(51) Int. Cl. H05K 7/20

(52) U.S. Cl. 361/679.46; 361/688; 361/695

(57) ABSTRACT

A circuit for controlling heat dissipation means for multiple units on a circuit board may comprise a first logical OR operation unit connected to said multiple units. The first logical OR operation unit is for performing a logical OR operation on a first set of signals output from the multiple units that represents whether any one of the multiple units has reached an overheated status. A resultant signal is output from the first logical OR operation to control an overheat protection unit connected to the first logical OR operation unit. A second logical OR operation unit is for performing a logical OR operation on a set of signals from the multiple units representing a relationship between the workload and the core temperature of a unit, whether a unit has reached an alert status and whether any of the multiple units has reached an overheated status.

### FIELD OF INVENTION

The present invention relates to chip heat dissipation, and more particularly to a method and circuit device for multiple chip heat dissipation on a single circuit board.

### CROSS-REFERENCES TO RELATED APPLICATIONS

This Application claims priority to Chinese Patent Application 200910148722.0, filed Jul. 1, 2009.

### BACKGROUND OF THE INVENTION

As higher computing performance is continually sought, the capability of existing single processor or multiple processor cores cannot meet the requirements for increasingly complicated graphics processes. Currently, there are some solutions of multiple core processors or multiple graphics processing units (GPUs) on a single graphics card to meet the above requirements, such as the Gemini™ GPU technology developed by ATI Corporation and SLI™ technology developed by NVIDIA Corporation. Based on these technologies, more than one GPU can be arranged on a single graphics card to increase computing performance. However, a problem of a large quantity of heat being generated by the multiple GPUs will occur accompanying the high performance.

Referring to FIG. 1, an existing graphics card having a dual GPU architecture. A first GPU 101 and a second GPU 102 are arranged on a graphics card 100. The first GPU 101 and the second GPU 102 may operate independently, alternatively or together according to the different graphics process requirements. core temperature of the GPU will rise as the workload of the GPU increases. When the core temperature reaches a level of alert (for example, about 95° C.), which means that the GPU is in a full load state, the performance of the GPU will decrease. When the core temperature continues to rise to a level of overheating (for example, about 125° C.), the GPU will be shut down automatically to avoid possible damage. Usually, a fan 103 will also be provided on the graphics card to dissipate the heat generated by the GPUs and thus make the core temperature decrease. In the dual GPU arrangement shown in FIG. 1, the operation of the fan 103 is controlled by monitoring the core temperature of the first GPU 101. Specifically, when the first GPU 101 operates with a light workload, the fan 103 will rotate slowly or even stop in order to decrease the noise caused by the fan rotation. When the first GPU 101 operates with a heavy workload, the rotation of the fan 103 will speed up and in some cases may reach full speed in order to dissipate enough heat to prevent the GPUs from overheating.

FIG. 2 illustrates a circuit diagram of a circuit for controlling the fan for the dual GPU graphics card shown in FIG. 1. In FIG. 2, a first GPU (GPU_1) 201, a second GPU (GPU_2) 202, an overheat protection unit 203, a fan control unit 204, a first logical OR operation unit (OR_1) 205 and a second logical OR operation unit (OR_2) 206 are shown. A signal having a square wave shape (referred to herein as a PWM_1 signal) is output at the pin PWM_1 of the GPU_1 201 and represents the relationship between the core temperature and the workload of the GPU_1 201. The higher the core temperature and the higher the_workload of the GPU, the larger the duty cycle of the square wave. The PWM_1 signal will be used to control the rotation speed of the fan via the OR_2 206. The fan control unit 204 is high-level enabled, and thus, the larger the duty cycle of the enabling signal, the faster the fan will rotate. When the duty cycle reaches one hundred percent (100%), which means that the GPU is in a full load state, the fan will rotate at full speed in order to cool down the GPU as quickly as possible.

The GPU_1 201 and the GPU_2 202 will also output an overheat alert signal from their pins OVERTEM_1 and OVERTEM_2 respectively when the GPU is overheated and needs to be shut down immediately. At this state, the core temperature of the GPU is usually 125° C. or above, for example. These overheat alert signals will be input into the OR_1 205 for a logical OR operation, and the resultant signal will be input to the overheat protection unit 203, which herein is a latch circuit, to protect the GPU and the graphics card from overheating. Specifically, an enabling signal will be input to the overheat protection unit 203 when either the GPU_1 201 or the GPU_2 202 reach a core temperature that would cause overheating. The enabling signal will trigger the state of the overheat protection unit 203 to change and be latched, and thus a high level signal (referred to as OUTPUT signal herein) will be output from the OUTPUT pin of the overheat protection unit 203. Simultaneously, a control signal will be output from the SHUTDOWN pin 203b and then used to shut down the power supply for both of the GPUs. Only if the user inputs an enabling signal from RESET pin 203a, will the latched state of the overheat protection unit 203 be released and the GPUs allowed to resume operation. The OUTPUT signal will also be sent to the OR_2 206 to make a logical OR operation with the PWM_1 signal, with the resultant signal used to control the fan to operate at a certain speed in order to cool down the GPUs.

It can be seen from the operation described above that the operation of the fan will be controlled by only the state of the GPU_1 201 (via the PWM_1 signal) and the overheat state of both the GPU_1 201 and the_GPU_2 202 (via the OUTPUT signal). In a case where the GPU_1 201 is working with a light load and the GPU_2 202 is working with a heavy load but not overheated yet, the fan may rotate slowly or even stop due to a small duty cycle of the PWM_1 signal. However, the core temperature of the GPU_2 202 may increase very rapidly since there is no way to cool it down. As a result, the GPU_2 202 will reach its overheat alert temperature very quickly and then both of the GPUs will be shut down by the enabling of the overheat protection unit 203. The user has to reset the overheat protection unit 203 manually in order to resume work, which will bring a lot of inconvenience to the user if it happens very frequently. Therefore, there is a need for an improved circuit and method to start the fan to cool down the GPUs timely, preferably before any of GPUs reaches a state of overheating, in order to prevent the GPUs from shutting down frequently due to overheating.

### SUMMARY OF THE INVENTION

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

In consideration of the above-identified shortcomings of the art, a circuit for controlling heat dissipation means for multiple units on a circuit board is provided. The circuit may comprise a first logical OR operation unit connected to said multiple units. The first logical OR operation unit performs a logical OR operation on a first set of signals output from each of the multiple units. A resultant signal is output from the first logical OR operation to control an overheat protection unit connected to the first logical OR operation unit. A signal within the first set of signals represents whether a unit from which the signal is output has reached an overheated status. The overheat protection unit shuts down the multiple units when any one of the multiple units is overheated.

A second logical OR operation unit is connected to the multiple units and the overheat protection unit. The second logical OR operation unit performs a logical OR operation on a second signal output from any one of the multiple units, a third set of signals output from each of the multiple units other than that from which the second signal is output and a fourth signal output from the overheat protection unit. The second logical OR operation unit also outputs a resultant signal to control operation of the heat dissipation means. A second signal represents a relationship between the workload and the core temperature of a unit from which the second signal is output. The third set of signals represents whether respective units from which signals within the third set of signals are output have reached an alert status and the fourth signal represents whether any of said multiple units has reached an overheated status.

According another aspect of the present invention, a method for controlling a heat dissipation means for multiple units on a circuit board is provided. The method may comprise selecting a first set of signals output by each of the multiple units, wherein a signal within the first set of signals represents whether a unit from which the signal is output has reached an overheated status. A logical OR operation is then performed with the selected set of first signals and a resulting signal is used to control an overheat protection unit. The overheat protection unit shuts down each of the_said multiple units when any one of said multiple units is overheated. Then a second signal output by one of said multiple units is selected. The second signal output represents a relationship between a workload and a core temperature of a unit from which the second signal is output. A third set of signals output from each of the multiple units other than that from which the second signal is output is also selected. The third set of signals represent whether respective units from which signals within the third set of signals are output have reached an alert status. A fourth signal output from the overheat protection unit is selected and the fourth signal represents whether any of the units has reached an overheated status. A logical OR operation is then performed with the second signal, the third set of signals and the fourth signal, with the resulting signal used to control operation of the heat dissipation means.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 shows an existing graphics card having a dual GPU architecture;

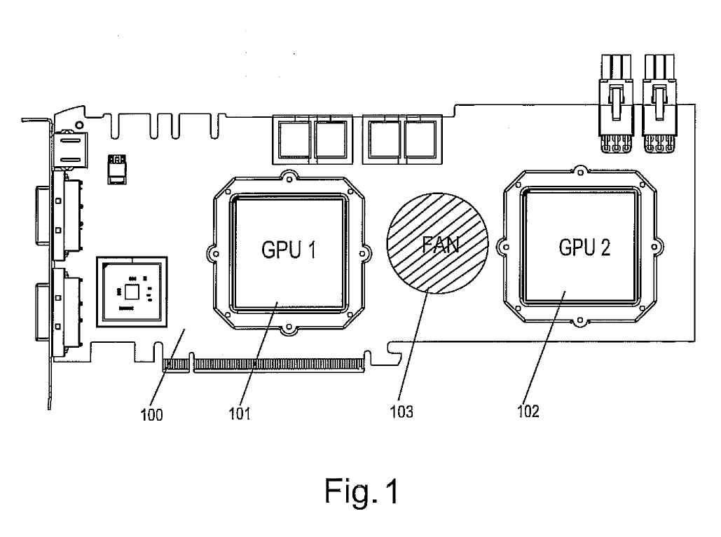

FIG. 2 shows a circuit diagram of a circuit for controlling the fan of the dual GPU graphics card shown in FIG. 1;

FIG. 3a shows a circuit diagram of an example circuit for controlling the fan of a dual GPU graphics card according to an embodiment of the present invention;

FIG. 3b is a diagram showing an example implementation of the control circuit shown in FIG. 3a;

FIG. 4 is a circuit diagram of an example circuit for controlling the fan of a multiple GPU graphics card according to an embodiment of the present invention;

FIG. 5 is a flow chart of an example process for controlling the fan of a multiple GPU graphics card according to an embodiment of the present invention.

### DETAILED DESCRIPTION

In the following description, numerous specific details are set forth to provide a more thorough understanding of the present invention. However, it will be apparent to one of skill in the art that the present invention may be practiced without one or more of these specific details. In other instances, certain well-known features have not been described in order to avoid obscuring the present invention.

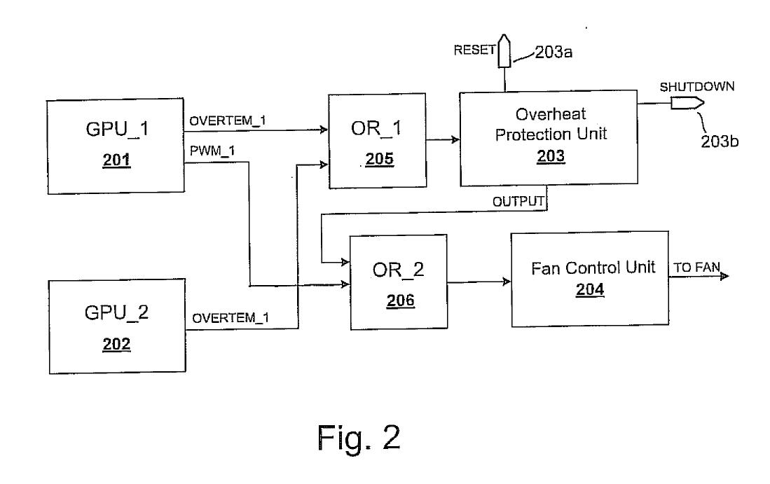

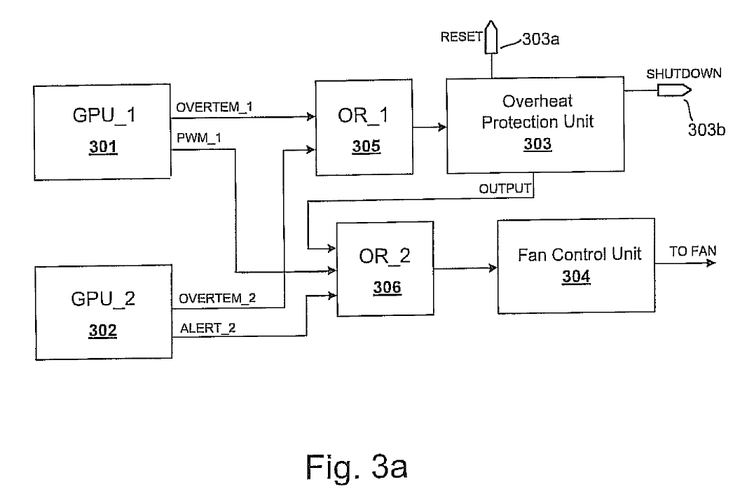

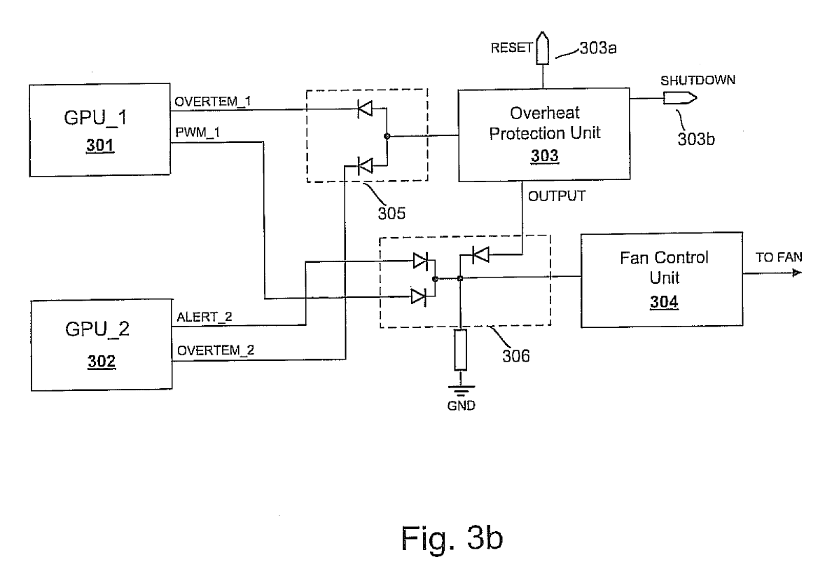

Referring to FIG. 3a, a circuit diagram of an example circuit for controlling the fan for a dual GPU graphics card according to an embodiment of the present invention is shown. FIG. 2 shows a first GPU (GPU_1) 301, a second GPU (GPU_2) 302, an overheat protection unit 303, a fan control unit 304, a first logical OR operation unit (OR_1) 305 and a second logical OR operation unit (OR_2) 306. Both the GPU_1 301 and the GPU_2 302 will output their overheat alert signal from their pins OVERTEM_1 and OVERTEM_2 respectively, after a logical OR operation in the OR_1 305, as input to the overheat protection unit 303. When either the GPU_1 301 or the GPU_2 302 is working at an unduly heavy load, the unit's respective core temperature may reach a temperature causing the unit to overheat (approximately 125° C., for example). At this time, an enabling signal will be output from the unit's pin OVERTEM. This signal will enable the overheat protection unit 303 to trigger the state of the overheat protection unit 303 to change and be latched, and thus output a high level signal from the pin OUTPUT. Simultaneously, a control signal will be output from a pin SHUTDOWN 303b and then used to shut down the power supply for both of the GPU_1 and the GPU_2. Only if the user inputs an enable signal from the pin RESET 303a, will the latched state of the overheat protection unit 303 be released and the GPU_1 301 and the GPU_2 302 be allowed to resume operation.

The circuit according to the present embodiment has a fan control unit 304 controlled by a signal resulting from a logical OR operation of three signals via the logical OR operation unit OR_2 306. These signals are a signal output from a pin PWM_1 of the GPU_1 301 (representing the relationship between the core temperature and the workload of the GPU_1 201 and preferably having a square wave shape), a signal output from a pin ALERT_2 of the GPU_2 302 (referred to as the ALERT_2 signal and representing whether the GPU_2 302 has reached an alert status), and a signal output from the pin OUTPUT of the overheat protection unit 303 (representing whether any of GPUs have reached an overheated status). For example, the input signal Fan Control Input of the fan control unit 304 will be:

Fan Control Input=(PWM_{—}1 of GPU_{—}1) logical OR (OUTPUT of Overheat Protection Unit) logical OR (ALERT_{—}2 of GPU_{—}2)

The ALERT_2 signal reflects a critical working state of the GPU_2 302, which means the GPU_2 302 is now in a state of full load and cannot endure any more load when the ALERT_2 signal is enabled. The GPU_2 302 would then need to be cooled down immediately. This status usually corresponds to a GPU core temperature of 95° C., for example.

In controlling the fan control unit 304 in the manner described above, when both the GPU_1 301 and the GPU_2 302 are working with a normal load, neither the ALERT_2 signal nor the OUTPUT signal will be enabled. The fan control unit 304 will be controlled only by the PWM_1 signal of the GPU_1 301. The higher the core temperature and the higher the workload of the GPU_1 301, the larger the duty cycle of the square wave and the faster the fan will rotate. When the duty cycle reaches 100%, representing that the GPU_1 301 may be in a state of full load, the fan will rotate at full speed in order to cool down the GPU_1 as quickly as possible. As the workload of the GPU_2 increases, the core temperature of the GPU_2 rises and when it reaches its alert temperature, an enabling ALERT_2 signal will be output and will result in an enabling signal generated at the output of the OR_2 306. This resultant signal will then be sent to the fan control unit 304 to make the fan rotate at full speed to cool down the GPU_2. If either of the workload of the GPU_1 301 or the GPU_2 302 continues to increase, the core temperature will continue to rise and reach an overheat alert temperature. At this time, the overheat protection unit 303 will output an enabling signal at the pin SHUTDOWN to shut down both the GPU_1 301 and the GPU_2 302 to prevent them from overheating and becoming damaged. In this way, the GPUs will be cooled down in a timely fashion before they reach a temperature that would cause them to overheat. For example, they may be cooled down to 30° C. below the temperature that would cause them to overheat, thereby avoiding frequent shutdown of the GPUs due to rapid overheating.

Heat dissipation is achieved by introducing an ALERT_2 signal of the GPU_2 302 and performing a logical OR operation with the existing signals to control the fan. The reason the ALERT_2 signal of the GPU_2 302 is chosen rather than the PWM_2 signal of the GPU_2 302 (which also reflects the change of the core temperature of the GPU as its workload varies) is because the PWM signals may be asynchronous between the different GPUs. If the fan control unit 304a is controlled by a signal resulting from a logical OR operation on the PWM_1 signal of the GPU_1 301 and the PWM_2 signal of the GPU_2 302, it may appear that when both of the GPU_1 301 and the GPU_2 302 work at a light load, they will both output a PWM signal having a low duty cycle, but the signal after the logical OR operation may have a large duty cycle due to an asynchronism between the signals. Thus the fan control unit 304 may mistakenly determine that the GPU has a high core temperature and should be cooled down immediately, resulting in the fan rotating at a high speed. Therefore, noise caused by the rotation of the fan will be introduced, which is disadvantageous for obtaining a quiet working status for the system.

FIG. 3b illustrates a diagram of an example implementation of the control circuit shown in FIG. 3a. In this embodiment, the fan control unit 304 may be a high-level enabled circuit. The OR_2 306 may be implemented with diodes whose ON direction is the same as the direction of the signal transmission in the circuit. As shown in FIG. 3b, each signal line input into the OR_2 306 is provided by a diode respectively. If either the PWM_1 signal of the GPU_1 301, the ALERT_2 signal of the GPU_2 302 or the OUTPUT signal from the overheat protection unit 303 becomes high, the input of the fan control unit 304 will be brought to a high level. If any of the above three signals is low, its respective diode will be OFF and block the signal from being input to the fan control unit 303. Thus, the signal competition at the input of the fan control unit 304 can be avoided.

Similarly, in this embodiment the overheat protection unit 303 may be a low-level enabled circuit, and the OR_1 305 may be implemented with diodes whose ON direction is opposite to the direction of the signal transmission in the circuit. As shown, each signal line input into the OR_1 305 is provided by a diode respectively. If either the signal OVERTEP_1 of the GPU_1 301 or the signal OVERTEP_2 of the GPU_2 302 becomes low, the input of the overheat protection unit 303 will be brought to a low level. If either of the above two signals is high, its respective diode will be OFF and block the signal from being input to the overheat protection unit 303. Thus, the signal competition at the input of the overheat protection unit 303 can be avoided.

It will be appreciated by those of ordinary skill in the art that the diode used herein is only an exemplary implementation for the first and second logical OR operation units 305 and 306 and any other circuit form commonly known and used in the art may be also adopted.

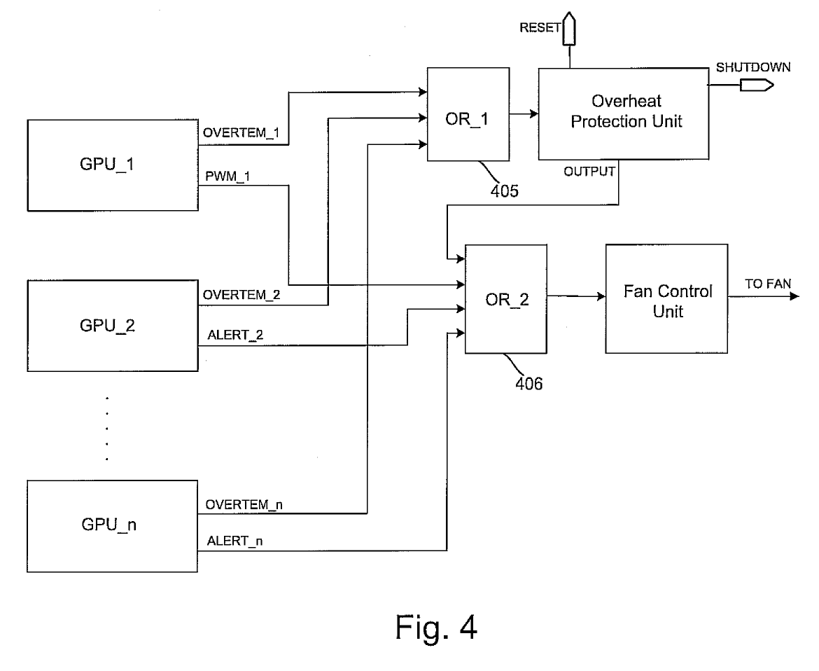

Referring next to FIG. 4, a circuit diagram of an example circuit for controlling the fan for a multiple GPU graphics card according to an embodiment of the present invention is illustrated. As shown in FIG. 4, if a new GPU_n (n being an integer more than 2) is to be arranged together with the existing multiple GPUs on the same graphics card, the circuit needs only to introduce the signal output from the pin OVERTEM_n of the GPU_n into the OR_1 unit 405 as an input, the OR_1 unit 405 thereby performing a logical OR operation with all of the existing input signals. Also, the alert signal from the pin ALERT of the GPU_n will be introduced into the OR_2 unit 406 as an input, the OR_2 unit 406 thereby performing a logical OR operation with the existing signals to control the fan together. It should be noted that the PWM signal may be chosen from any of the multiple GPUs, but only one PWM signal is sufficient for controlling the fan according to the present embodiment.

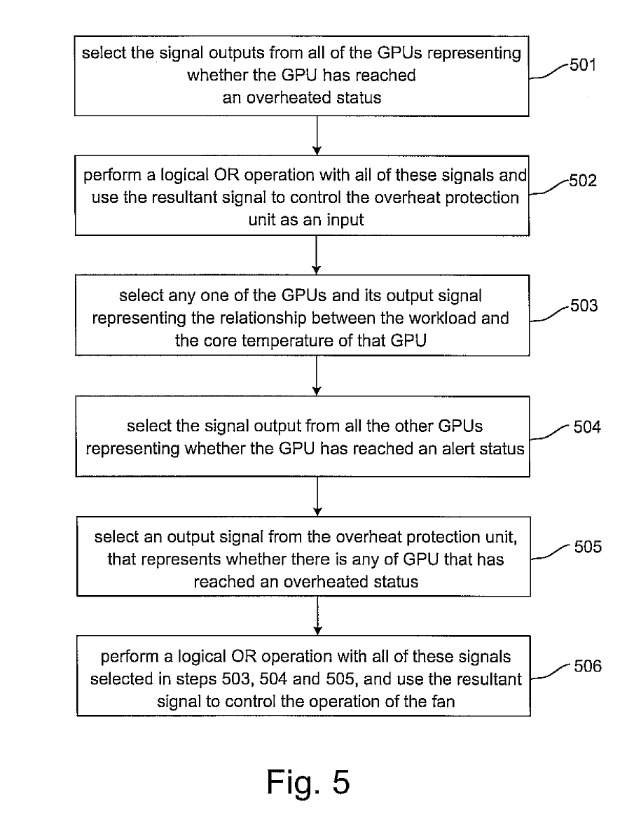

Referring next to FIG. 5, a flow chart of an example process for controlling the fan for a multiple GPU graphics card according to an embodiment of the present invention is shown. At step 501, the signal outputs from all of the GPUs representing whether the respective GPU has reached an overheated status are selected. At step 502, a logical OR operation is performed with all of these signals and the resultant signal is used to control the overheat protection unit as an input. At step 503, any one of the GPUs and its output signal representing the relationship between the workload and the core temperature of that GPU is selected. Next, at step 504, the signals output from all the other GPUs representing whether the GPU has reached an alert status are selected. At step 505, an output signal from the overheat protection unit that represents whether there is any GPU that has reached an overheated status is selected. At step 506, a logical OR operation is performed with all of these signals selected in steps 503, 504 and 505, and the resultant signal is used to control the operation of the fan. For example, this resultant signal may be used to control the rotational speed of the fan.

Besides the multiple GPUs on a graphics card, the circuit and method as described above may be applied in various other chips, processors, circuit boards and add-in cards in cases where there is a need for heat dissipation of multiple units. The fan may also be replaced by any other means for heat dissipation.

It is noted that the foregoing examples have been provided merely for the purposes of explanation and are in no way to be construed as limiting of the present invention. While the invention has been described with reference to various embodiments, it is understood that the words which have been used herein are words of description and illustration, rather than words of limitation. Further, although embodiments have been described herein with reference to particular means and materials, the invention is not intended to be limited to the particulars disclosed herein; rather, the invention extends to all functionally equivalent structures, methods and uses, such as are within the scope of the appended claims. Those skilled in the art, having the benefit of the teachings of this specification, may effect numerous modifications thereto and changes may be made without departing from the scope and spirit of the invention in its aspects.

1-20. (canceled)

21. A circuit for controlling heat dissipation for a plurality of units on a circuit board, comprising:
a first logical OR unit, operable to receive a first plurality of signals from the plurality of units, wherein the first logical OR unit is operable to perform a logical OR operation with the first plurality of signals, a resultant signal from the first logical OR unit is operable to control an overheat protection unit, wherein the first plurality of signals indicate whether a unit of the plurality of units has reached an overheated status, the overheat protection unit operable to shut down the plurality of units when one of the plurality of units overheats; and
a second logical OR unit, operable to receive a second signal from one of the plurality of units, a third plurality of signals from the plurality of units other than the unit outputting the second signal, and a fourth signal from the overheat protection unit, wherein the second logical OR unit is operable to perform a logical OR operation with the second signal, the third plurality of signals and the fourth signal, a resultant signal from the second logical OR unit operable to control the operation of a heat dissipation means, wherein the second signal represents a relationship between a workload and a core temperature of a unit outputting the second signal, wherein the third plurality of signals comprises signals indicating whether respective units have reached an alert status, the fourth signal indicating whether any of the plurality of units has reached an overheated status.

22. The circuit of claim 21, wherein the heat dissipation means is a fan.

23. The circuit of claim 21, wherein the plurality of units are any combination of Graphics Processing Units (GPU), Central Process Units (CPU), processors and chips.

24. The circuit of claim 21, wherein the overheated status is a core temperature of a unit reaching approximately 125° C.

25. The circuit of claim 21, wherein the alert status is a core temperature of a unit reaching approximately 95° C.

26. The circuit of claim 21, wherein the second signal has a square wave shape.

27. The circuit of claim 21, wherein the overheat protection unit has an input for resetting the unit by an external input.

28. A system for controlling heat dissipation for a plurality of units on a circuit board, the system comprising:
an overheat protection unit, operable to shut down the plurality of units if any one of the plurality of units overheats;
a heat dissipation means control unit, operable to control operation of a heat dissipation means;
a first logical OR unit, operable to receive a first plurality of signals from the plurality of units, wherein the first logical OR unit is operable to perform a logical OR operation with the first plurality of signals, a resultant signal from the first logical OR unit operable to control the overheat protection unit, wherein the first plurality of signals indicate whether a unit of the plurality of units has reached an overheated status; and
a second logical OR unit, operable to receive a second signal from one of the plurality of units, a third plurality of signals from the plurality of units other than the unit outputting the second signal, and a fourth signal from the overheat protection unit, wherein the second logical OR unit is operable to perform a logical OR operation with the second signal, the third plurality of signals and the fourth signal, a resultant signal from the second logical OR unit operable to control the operation of the heat dissipation means, wherein the second signal represents a relationship between a workload and a core temperature of a unit outputting the second signal, wherein the third plurality of signals comprises signals indicating whether respective units have reached an alert status, the fourth signal indicating whether any of the plurality of units has reached an overheated status.

29. The system of claim 28, wherein the heat dissipation means is a fan.

30. The system of claim 28, wherein the plurality of units are any combination of Graphics Processing Units (GPU), Central Process Units (CPU), processors and chips.

31. The system of claim 28, wherein the overheated status is a core temperature of a unit reaching approximately 125° C.

32. The system of claim 28, wherein the alert status is a core temperature of a unit reaching approximately 95° C.

33. The system of claim 28, wherein the second signal has a square wave shape.

34. The system of claim 28, wherein the overheat protection unit has an input for resetting said unit by an external input.

35. A method for controlling heat dissipation for a plurality of units on a circuit board, the method comprising:
selecting a first plurality of signals from the plurality of units, wherein the first plurality of signals indicate whether a unit of the plurality of units has reached an overheated status;
performing a logical OR operation with the first plurality of signals and using a resultant signal to control an overheat protection unit, the overheat protection unit shutting down the plurality of units when any one of the plurality of units overheats;
selecting a second signal from one of the plurality of units, the second signal representing a relationship between a workload and a core temperature of a unit outputting the second signal;
selecting a third set of signals from the plurality of units other than the unit outputting the second signal, the third plurality of signals comprising signals indicating whether respective units have reached an alert status;
selecting a fourth signal from the overheat protection unit, the fourth signal indicating whether any of the plurality of units has reached an overheated status; and
performing a logical OR operation with the second signal, the third plurality of signals, and the fourth signal, and using a resultant signal to control operation of a heat dissipation means.

36. The method of claim 35, wherein the heat dissipation means is a fan.

37. The method of claim 35, wherein the plurality of units are any combination of Graphics Processing Units (GPU), Central Process Units (CPU), processors and chips.

38. The method of claim 35, wherein the overheated status is a core temperature of a unit reaching approximately 125° C.

39. The method of claim 35, wherein the alert status is a core temperature of a unit reaching approximately 95° C.

40. The method of claim 35, wherein the overheat protection unit has an input for resetting the unit by an external input.
